(19) United States
(12) Patent Application Publication
(10) Pub. No.: US 2002/0055273 A1
(43) Pub. Date: May 9, 2002

(54) Semiconductor device having single silicon oxide nitride gas insulating layer

(75) Inventor: Eiji Hasegawa, Tokyo (JP)

Correspondence Address: YOUNG & THOMPSON, 745 SOUTH 23RD STREET 2ND FLOOR, ARLINGTON, VA, 22202

(73) Assignee: NEC Corporation, Tokyo (JP)

(21) Appl. No.: 09/986,056

(22) Filed: Nov. 7, 2001

Related U.S. Application Data
(62) Division of application No. 09/635,532, filed on Aug. 9, 2000.

(30) Foreign Application Priority Data
Aug. 10, 1999 (JP) 226192/1999

(51) Int. Cl. H01L 21/44

(52) U.S. Cl. 438/794

(57) ABSTRACT

In a semiconductor device including a semiconductor substrate and a gate electrode layer, a single silicon oxide nitride (SiON) layer is sandwiched by the semiconductor substrate and the gate electrode layer.

### BACKGROUND OF THE INVENTION

1. Field of the Invention

The present invention relates to a semiconductor device, and more particularly, to a metal oxide silicon (MOS) transistor and its manufacturing method.

2. Description of the Related Art

Generally, a MOS transistor is constructed by a silicon substrate, a gate electrode and a gate insulating layer sandwiched by the silicon substrate and the gate electrode. The gate insulating layer is made of thermally grown silicon oxide.

As a MOS transistor is more fined and its operation voltage is lower, the silicon oxide gate insulating layer is thinner. As a result, when the silicon oxide gate insulating layer is several nm, for example, the hot carrier immunity characteristics and the electrostatic breakdown voltage characteristics of the silicon oxide gate insulating layer are remarkably deteriorated.

In order to improve the hot carrier immunity characteristics and the electrostatic breakdown voltage characteristics, a gate insulating layer made of a double structure of silicon oxide (SiO₂) and silicon nitride (Si₃N₄) has been suggested. This will be explained later in detail.

In a MOS transistor including a SiO₂/Si₃N₄ gate insulating layer, however, since there are weak bonds of Si—H in the gate insulating layer so that the number of electron traps therein is increased, the hot carrier immunity characteristics are deteriorated. Also, since interface states are induced by the small freedom of Si—N—Si bonds, a threshold voltage and an ON-current (drive current) greatly fluctuate. Further, since physical stress and crystal defects such as dangling bonds are generated due to the double structure SiO₂/Si₃N₄, the lifetime is decreased and the reliability is deteriorated.

Note that JP-A-10-163197 discloses a silicon nitride gate insulating layer grown by using nitrogen in a single atom form generated by thermal dissociation. As a result, no bonds of Si—H are included in the gate insulating layer. In JP-A-10-163197, however, there are Si—N bonds having a small freedom in the gate insulating layer, so that a threshold voltage and an ON-current greatly fluctuate.

### SUMMARY OF THE INVENTION

It is an object of the present invention to provide a semiconductor device having a gate insulating layer excluding Si—H bonds and suppressing distorted Si—N—Si bonds, physical stress and crystal defects therein.

According to the present invention, in a semiconductor device including a semiconductor substrate and a gate electrode layer, a single silicon oxide nitride (SiON) layer is sandwiched by the semiconductor substrate and the gate electrode layer.

### BRIEF DESCRIPTION OF THE DRAWINGS

The present invention will be more clearly understood from the description set forth below, as compared with the prior art, with reference to the accompanying drawings, wherein:

FIGS. 1A through 1K are cross-sectional views for explaining a prior art method for manufacturing a semiconductor device;

FIG. 2 is a graph showing the atom concentration of the gate insulating layer of FIG. 1K;

FIG. 3 is a diagram showing the structure of the gate insulating layer of FIG. 1K;

FIG. 4 is a diagram showing the structure of the silicon nitride layer of FIG. 1K;

FIGS. 5A and 5B are cross-sectional views for explaining the hot carrier characteristics of an N-channel MOS transistor;

FIG. 6 is a graph showing the ON-current deviation characteristics of the MOS transistor of FIG. 1K;

FIG. 7 is a graph showing the flat band voltage characteristics of the MOS transistor of FIG. 1K;

FIG. 8 is a graph showing the ON-current characteristics of the MOS transistor of FIG. 1K;

FIG. 9 is a graph showing the time-dependent-dielectric-breakdown characteristics of the MOS transistor of FIG. 1K;

FIGS. 10A through 10J are cross-sectional views for explaining an embodiment of the method for manufacturing a semiconductor device according to the present invention;

FIG. 11 is a graph showing the atom concentration of the gate insulating layer of FIG. 10J;

FIG. 12 is a diagram showing the structure of the gate insulating layer of FIG. 10J;

FIG. 13 is a graph showing the ON-current deviation characteristics of the MOS transistor of FIG. 10J;

FIG. 14 is a graph showing the flat band voltage characteristics of the MOS transistor of FIG. 10J;

FIG. 15 is a graph showing the ON-current characteristics of the MOS transistor of FIG. 10J; and

FIG. 16 is a graph showing the time-dependent-dielectric-breakdown characteristics of the MOS transistor of FIG. 10J.

### DESCRIPTION OF THE PREFERRED EMBODIMENT

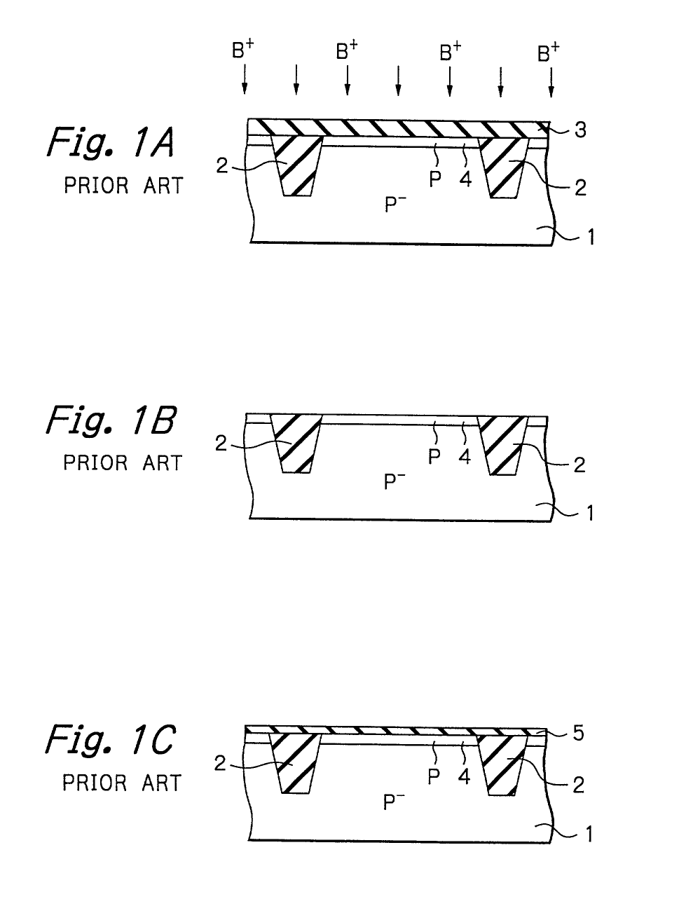

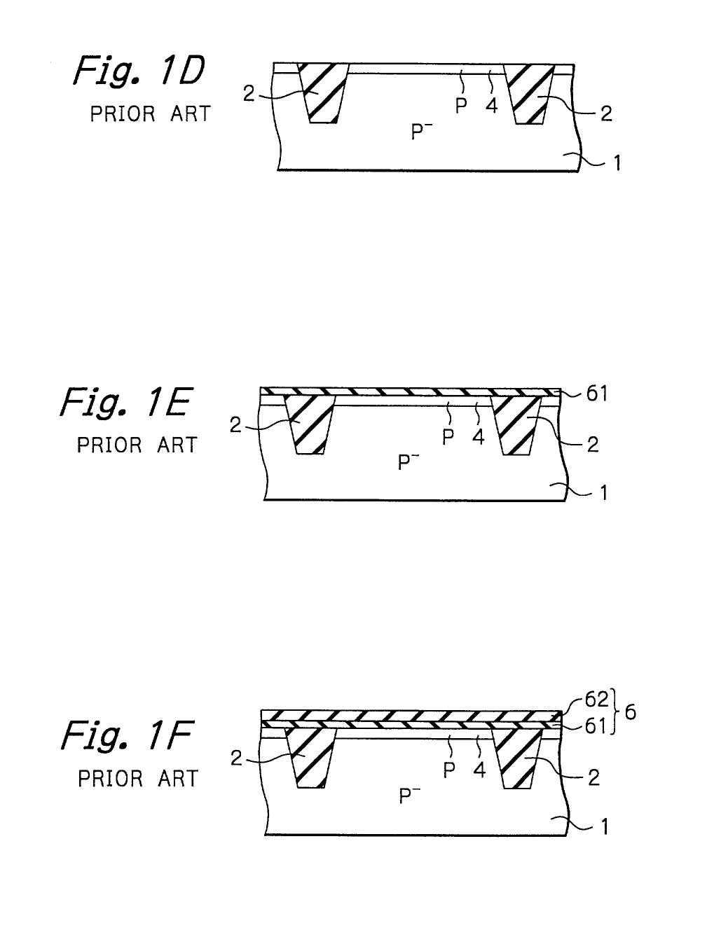

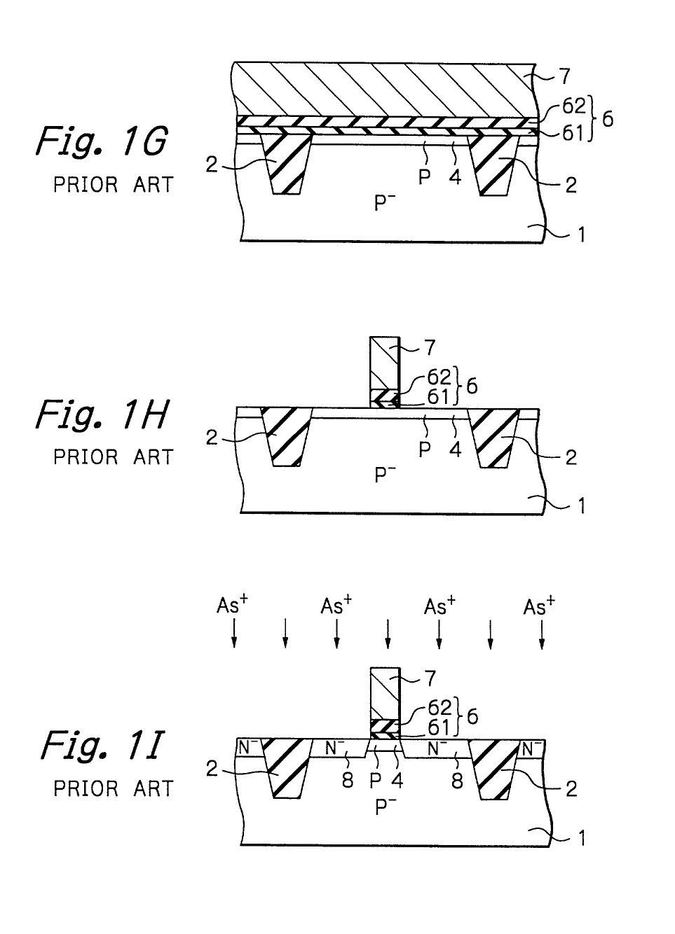

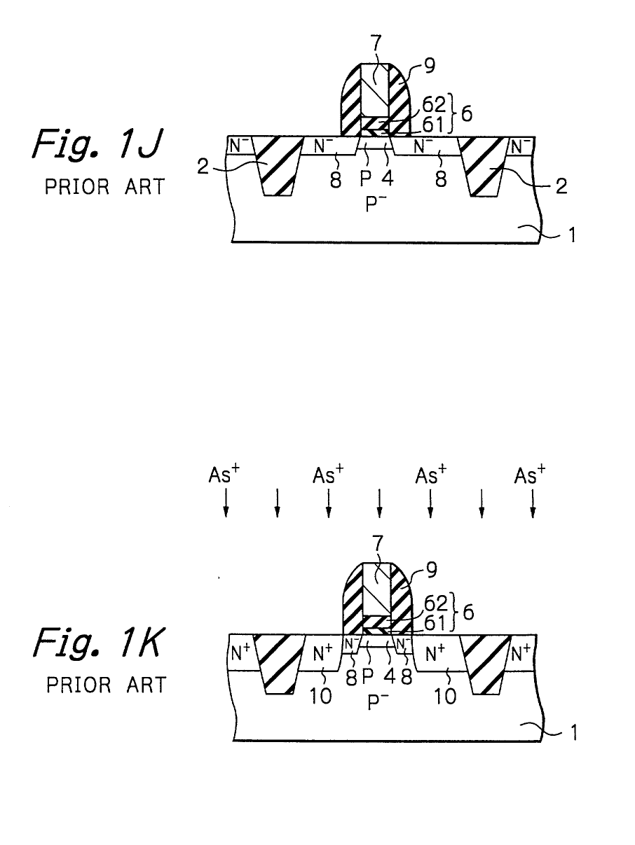

Before the description of the preferred embodiment, a prior art method for manufacturing a semiconductor device will be explained with reference to FIGS. 1A through 1K.

First, referring to FIG. 1A, a shallow trench isolation (STI) layer 2 made of silicon oxide for isolating elements from each other is buried in a P⁻-type single-crystalline silicon substrate 1. Then, an about 20 nm thick sacrifice silicon oxide layer 3 is grown by thermally oxidizing the silicon substrate 1. Then, boron ions are implanted into the silicon substrate 1 to form a P-type impurity diffusion region 4 within the silicon substrate 1. Note that the P-type impurity diffusion region 4 is used for adjusting the threshold voltage of an N-channel MOS transistor which will be formed.

Next, referring to FIG. 1B, the sacrifice silicon oxide layer 3 is removed by an etching process using a diluted fluoric acid solution for about 1.5 minutes.

Next, referring to FIG. 1C, the device is cleaned and rinsed by ammonium hydrogen peroxide and sulfuric acid hydrogen peroxide. As a result, an about 1 nm thick chemical or natural silicon oxide layer 5 is formed on the entire surface.

Next, referring to FIG. 1D, the natural silicon oxide layer 5 is removed by an etching process using a diluted fluoric acid solution of 49 percent HF/H₂O=1/100 at a temperature of about 25° C.

Next, referring to FIG. 1E, an about 0.7 to 1.0 nm thick silicon oxide layer 61 is grown by thermally oxidizing the silicon substrate 1 using a rapid thermal process (RTP) in an oxygen atmosphere at a temperature of about 850° C. for about 7 seconds at a pressure of about 50 Torr (6666 Pa).

Next, referring to FIG. 1F, an about 2.0 nm thick silicon nitride layer 62 is deposited by a low pressure chemical vapor deposition (LPCVD) process under an atmosphere of SiH₄/NH₃ gas at a temperature of about 630° C. and a pressure of about 10 Torr (1333 Pa).

Note that the silicon oxide layer 61 and the silicon nitride layer 62 form a gate insulating layer 6.

Next, referring to FIG. 1G, a heating process is carried out in an oxygen atmosphere at a temperature of about 800° C. for about 10 seconds at an atmospheric pressure. Then, an about 150 nm thick polycrystalline silicon layer 7 is deposited on the entire surface by a CVD process at a temperature of about 620° C.

Next, referring to FIG. 1H, the polycrystalline silicon layer 7, the silicon nitride layer 62 and the silicon oxide layer 61 are patterned by a photolithography and etching process. As a result, the etched polycrystalline silicon layer 7 forms a gate electrode.

Next, referring to FIG. 1I, arsenic ions are implanted into the silicon substrate 1 by using the polycrystalline silicon layer 7 as a mask. As a result, an N⁻-type impurity diffusion region 8 for a lightly-doped drain (LDD) structure is formed within the silicon substrate 1.

Next, referring to FIG. 1J, a silicon oxide layer is deposited on the entire surface by a CVD process, and the silicon oxide layer is etched back by an anistropic etching process. As a result, a side-wall silicon oxide layer 9 is formed on the side-walls of the polycrystalline silicon layer 7 and the gate insulating layer 6.

Finally, referring to FIG. 1K, arsenic ions are implanted into the silicon substrate 1 by using the polycrystalline silicon layer 7 and the side-wall silicon oxide layer 9 as a mask. As a result, an N⁺-type impurity diffusion region 10 as a source/drain region is formed within the silicon substrate 1.

Thus, an N-channel MOS transistor is completed.

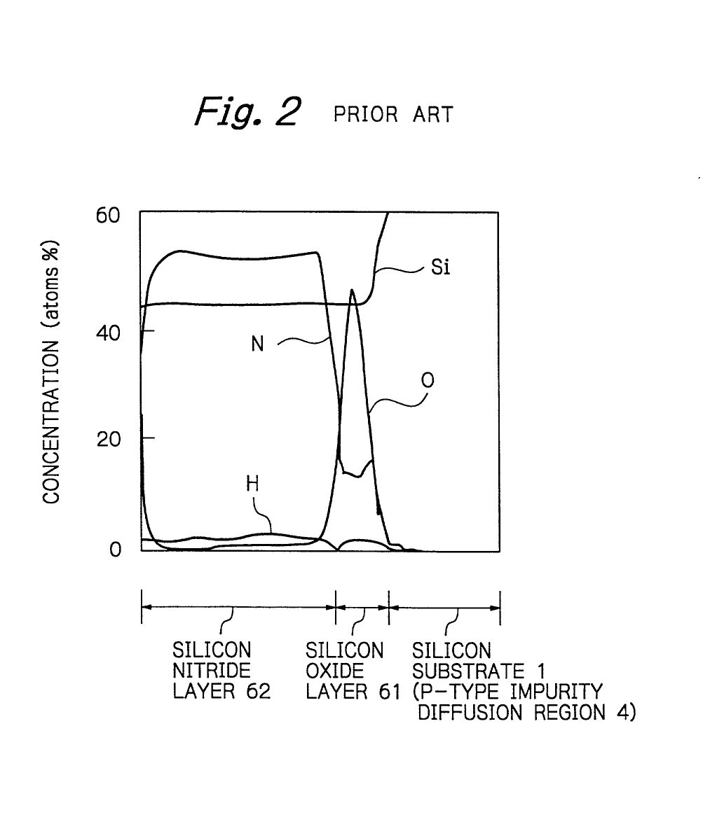

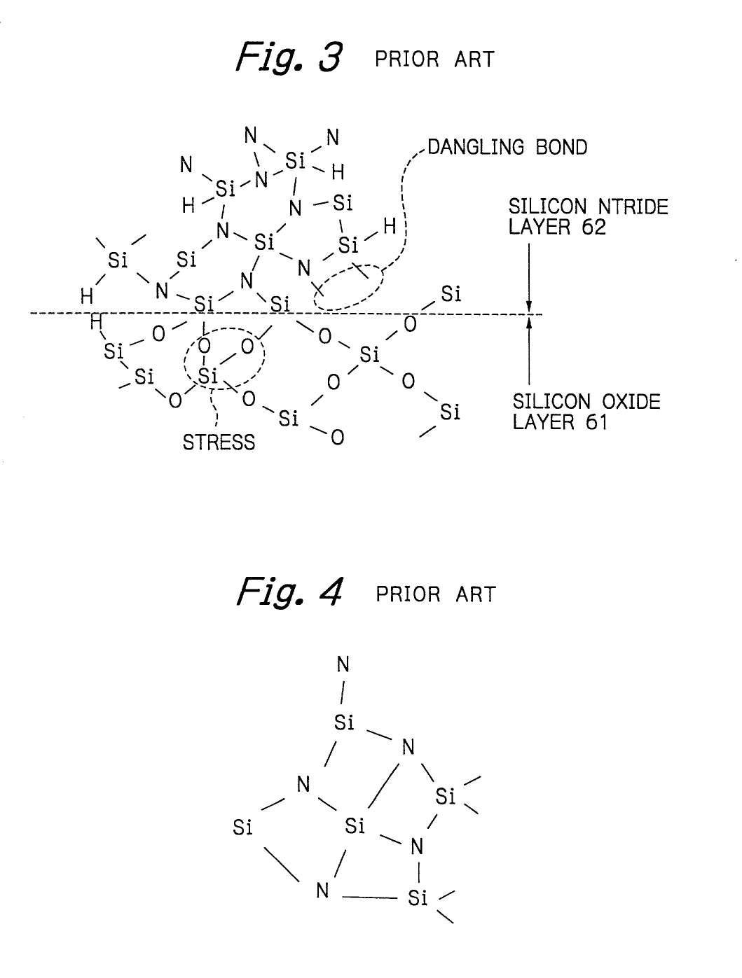

FIG. 2 is a graph showing the nitrogen, oxygen, hydrogen and silicon concentration of the gate insulating layer 6 of FIG. 1K, FIG. 3 is a diagram showing the structure of the gate insulating layer 6 of FIG. 1K, and FIG. 4 is a diagram showing the silicon nitride structure of the silicon nitride layer 62 of FIG. 1K.

As illustrated in FIGS. 2 and 3, hydrogen atoms are introduced by the reaction of SiH₄ and NH₃ into the silicon nitride layer 62. As a result, weak bonds of Si—H are generated in the silicon nitride layer 62.

Also, as illustrated in FIG. 2, there is a mismatch interface between the silicon oxide layer 61 and the silicon nitride layer 62, which creates a large physical stress and a crystal defect such as dangling bonds.

Further, as illustrated in FIG. 4, since one nitrogen atom has three bond hands, if nitrogen atoms are bonded with silicon atoms, the freedom of the bonds is small which would create stress therein.

The weak bonds of Si—H in the silicon nitride layer 62 increase the number of electrode traps therein, which would deteriorate the hot carrier immunity characteristics.

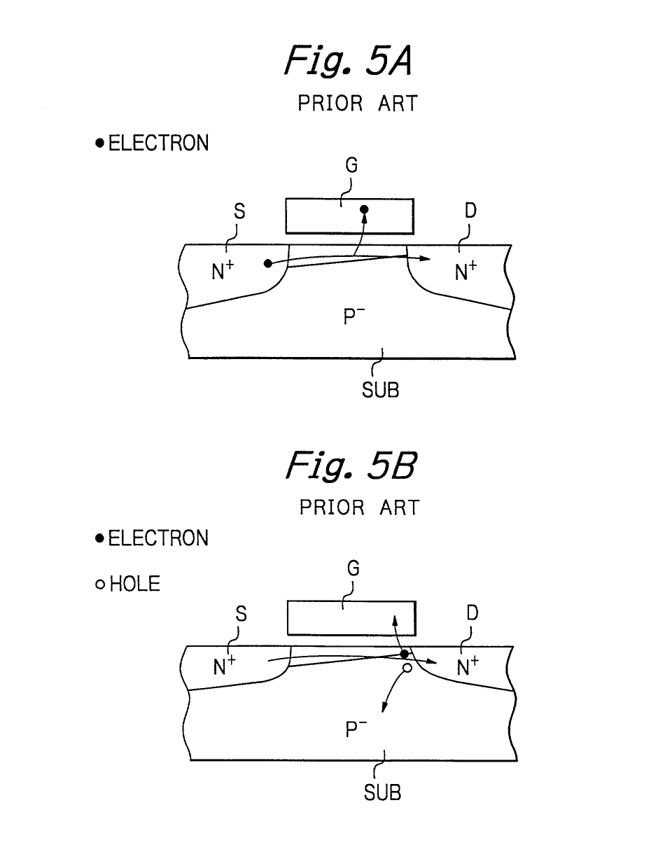

The hot carrier characteristics are explained next with reference to FIGS. 5A and 5B, which illustrate an N-channel MOS transistor.

As illustrated in FIG. 5A, electrons are accelerated by a horizontal electric field between a source region S and a drain region D through a channel region of a substrate SUB. As a result, the electrons have a large energy, and therefore, are called hot electrons. Some of the hot electrons are injected via a gate insulating layer to a gate electrode G, which is called a channel hot carrier (CHC) injection.

On the other hand, as illustrated in FIG. 5B, the hot electrons are further accelerated by an extremely high electric field in the proximity of the drain region D, so that electron-hole pairs are generated by the avalanche effect. Also, some of electrons of the electron-hole pairs are injected via the gate insulating layer to the gate electrode G, which is called a drain avalanche hot carrier (DAHC) injection.

The hot electrons injected into the silicon nitride layer 62 separate the weak bonds of Si—H, so that interface states are formed therein. Such interface states would fluctuate a threshold voltage and an ON-current, and also would increase a leakage current.

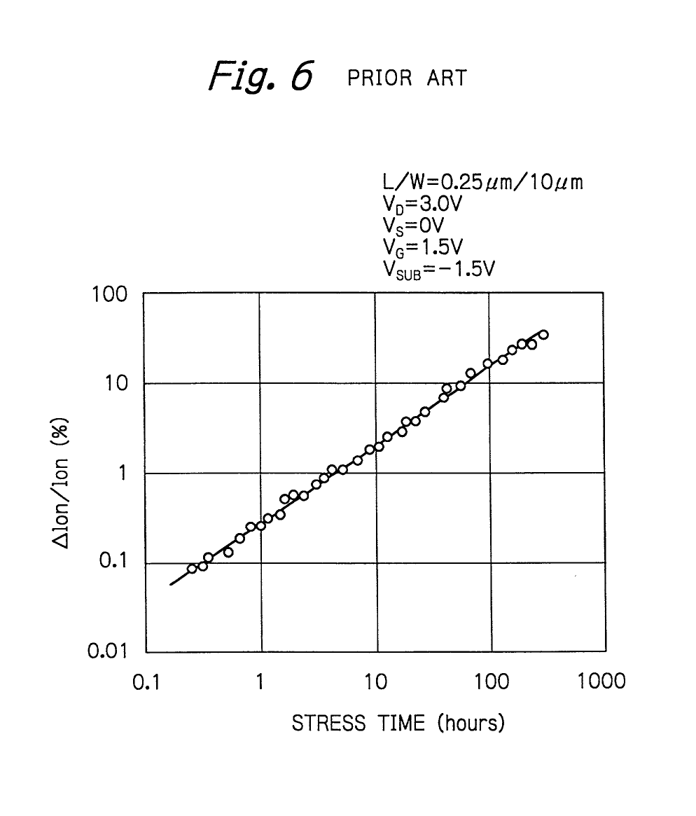

In FIG. 6, which shows the ON-current deviation characteristics of the MOS transistor of FIG. 1K, the abscissa designates a stress time and the ordinate designates an ON-current deviation, where the conditions of the MOS transistor are as follows:

thickness of the gate insulating layer 6: 2 nm (silicon oxide equivalent thickness);

gate length: 0.25 μm;

gate width: 10 μm;

drain voltage: 3.0 V;

source voltage: 0 V;

gate voltage: 1.5 V; and

substrate voltage: −1.5 V.

As shown in FIG. 6, the ON-current deviation duration characteristics are deteriorated by the hot carrier characteristics.

In order to improve the ON-current deviation characteristics, it is essential to remove the weak bonds of Si—H from the gate insulating layer 6.

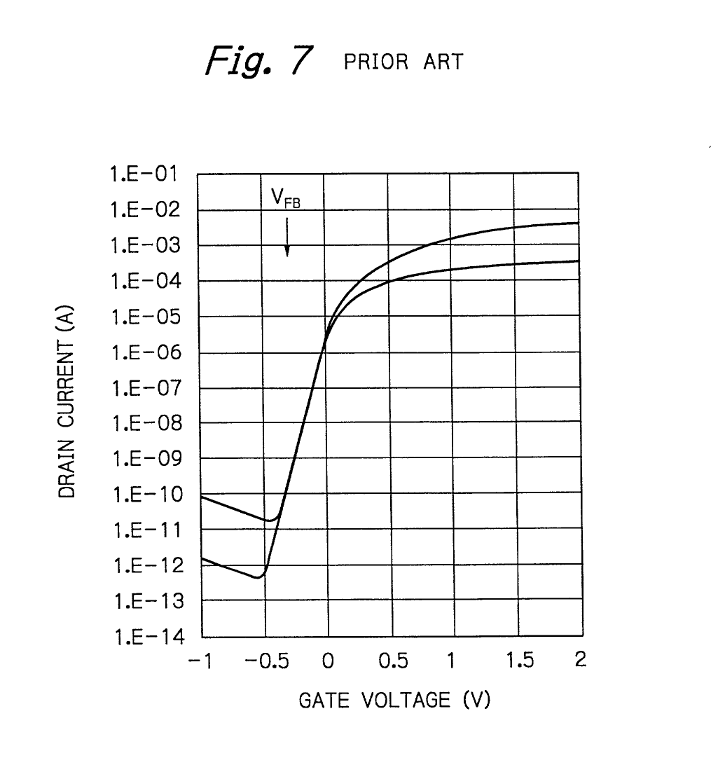

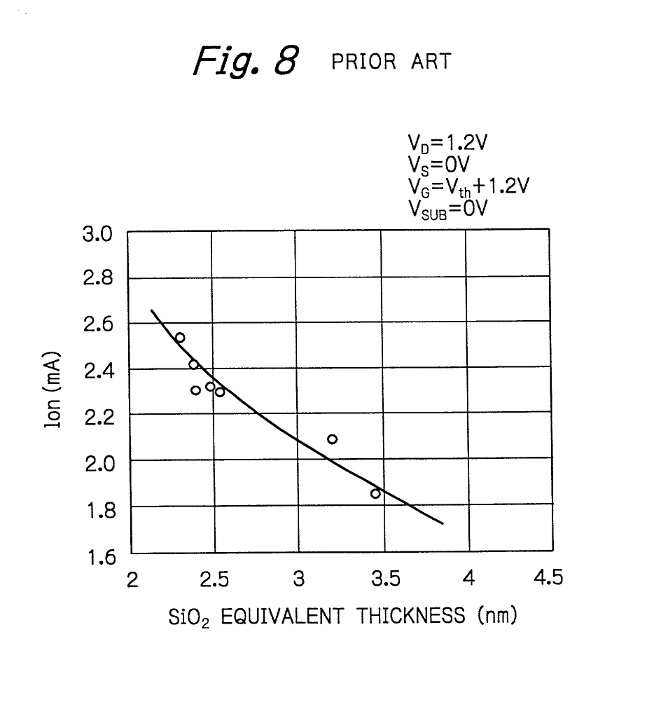

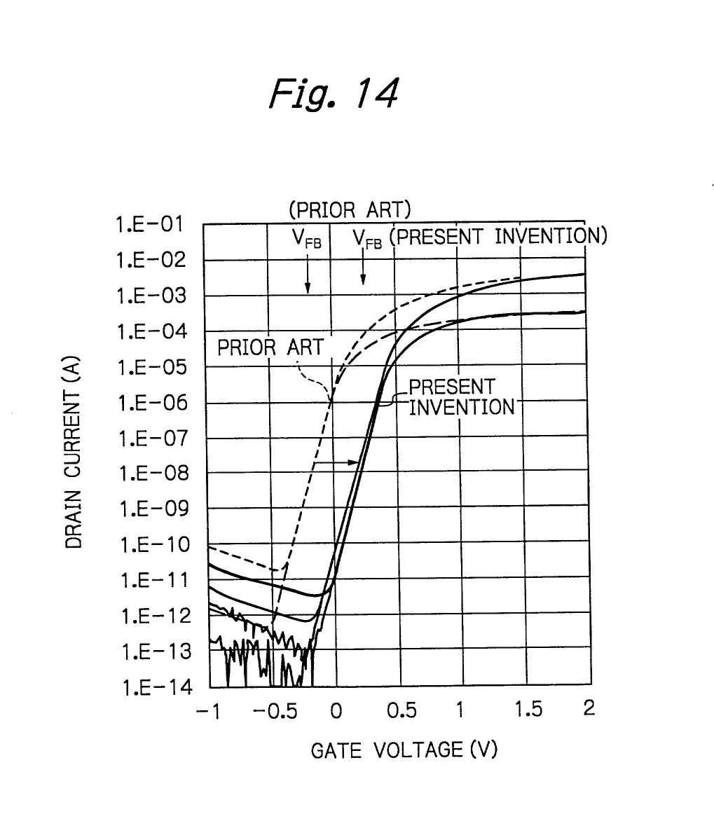

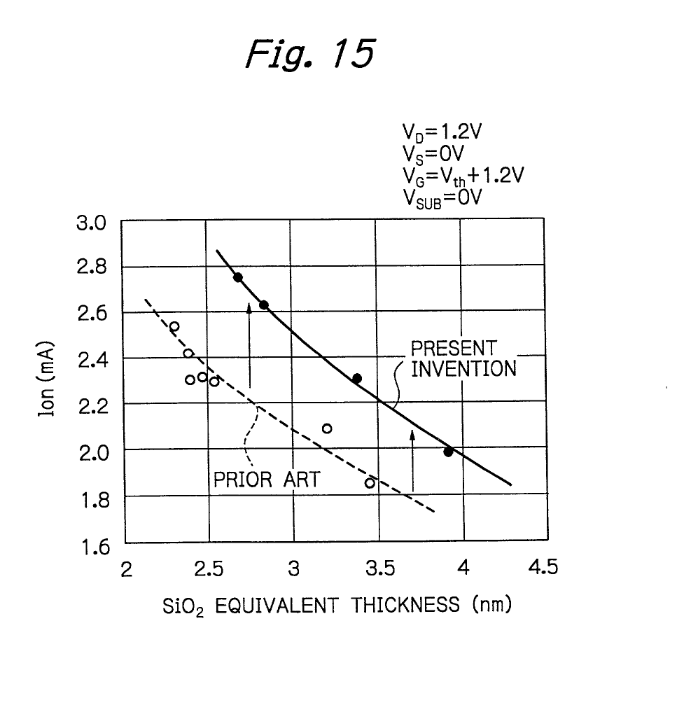

Also, the above-mentioned small freedom of Si—N bonds invites positive fixed charges in the silicon nitride layer 62. The reason is unclear; however, the inventor believes that such positive fixed charges are due to a paramagnetic defect caused by the distortion of the Si—N bonds. The positive fixed charges electrostatically scatter carriers such as electrons and holes passing through a channel region of the silicon substrate 1. As a result, the presence of positive fixed charges in the silicon nitride layer 62 can be observed as a deviation of a flat band voltage V_{FB} as shown in FIG. 7 (also see FIG. 14) and an ON-current as shown in FIG. 8 (also see FIG. 15).

As shown in FIG. 7, the flat band voltage V_{FB} is shifted on the negative side, which shows the presence of carrier scattering due positive fixed charges in the silicon nitride layer 62.

As shown in FIG. 8, the ON-current is relatively small, which also shows the presence of positive fixed charges in the silicon nitride layer 62.

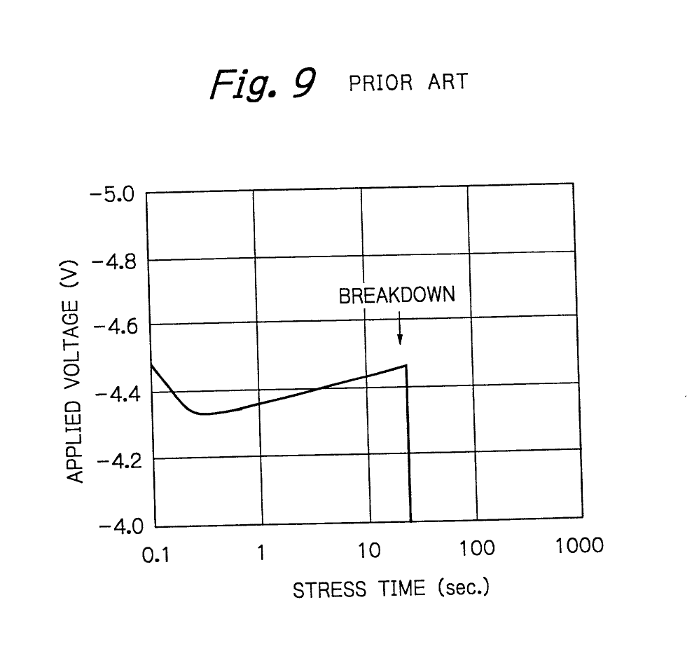

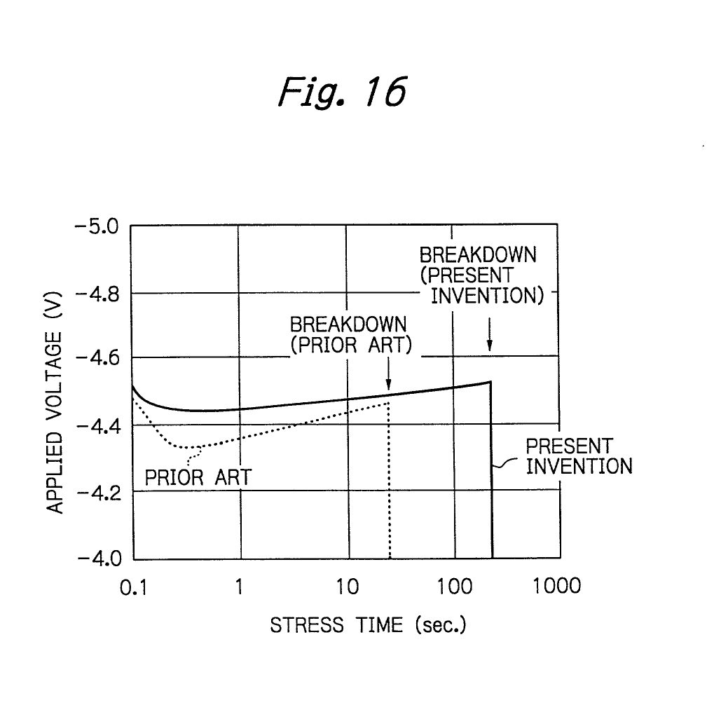

The large physical stress and the crystal defect such as dangling bonds due to the interface between the silicon oxide layer 61 and the silicon nitride layer 62 are observed by a time-dependent-dielectric-breakdown (TDDB) test as shown in FIG. 9 (also see FIG. 16), where a stress current density −1.0 A/cm² is forced to flow through the gate insulating layer 6 at a temperature of about 25° C. That is, the voltage applied to the gate electrode 7 greatly fluctuates, which shows a large number of trap generation in the insulating layer 6. Additionally, the stress time at the breakdown point is small, which shows a small lifetime, i.e., a low reliability.

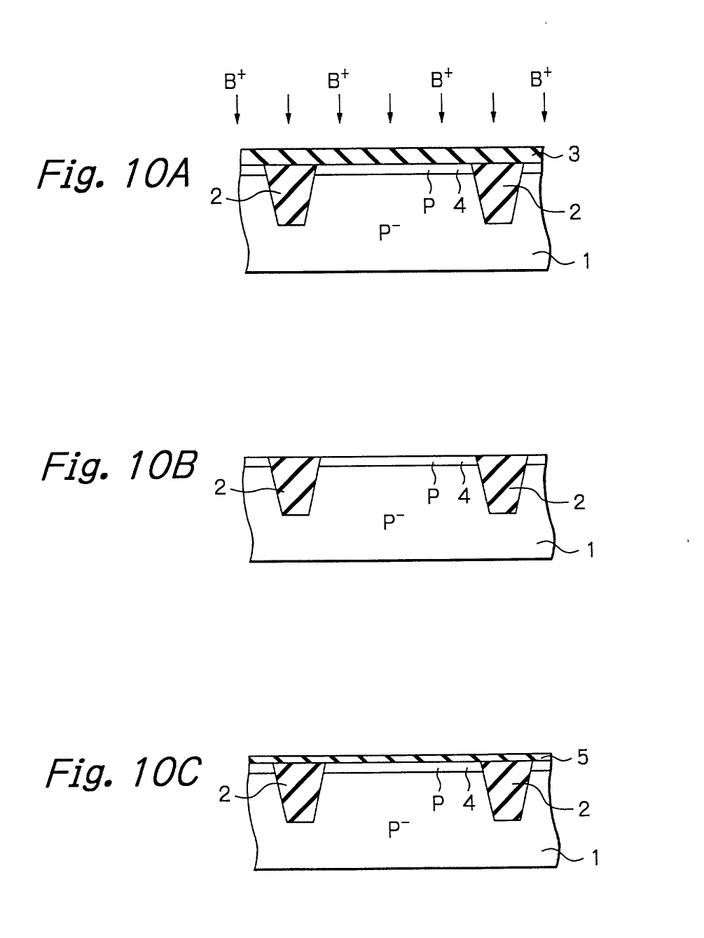

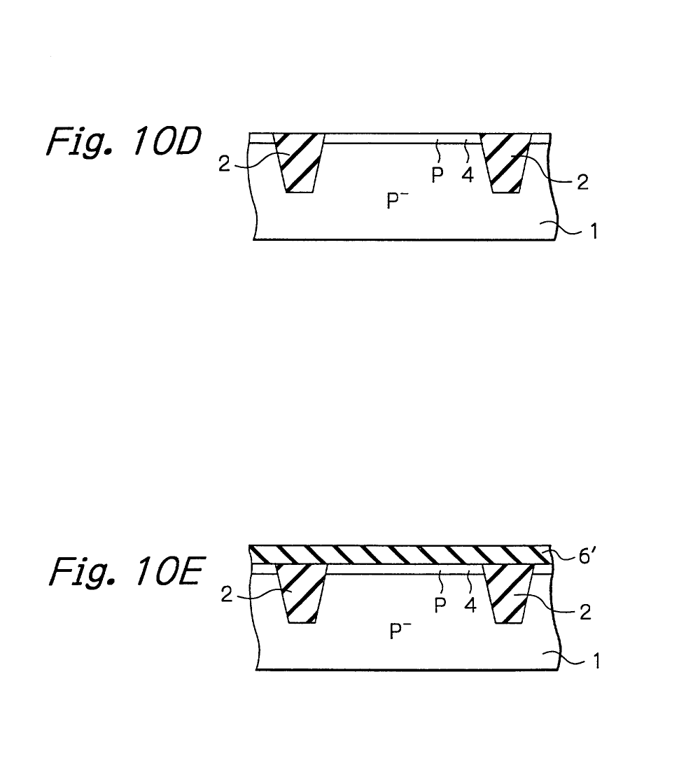

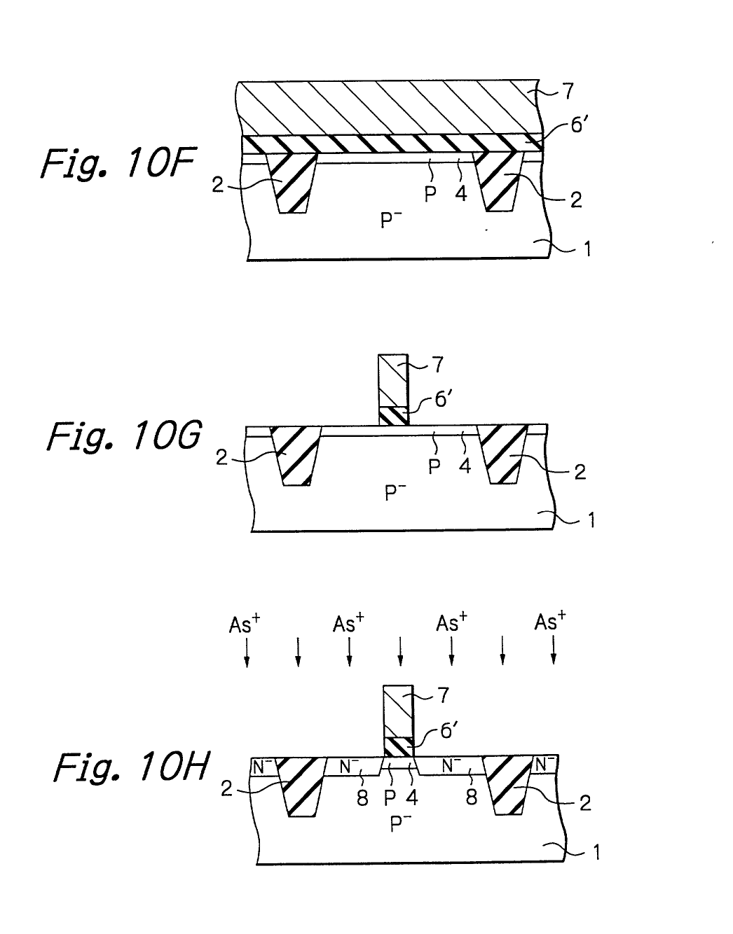

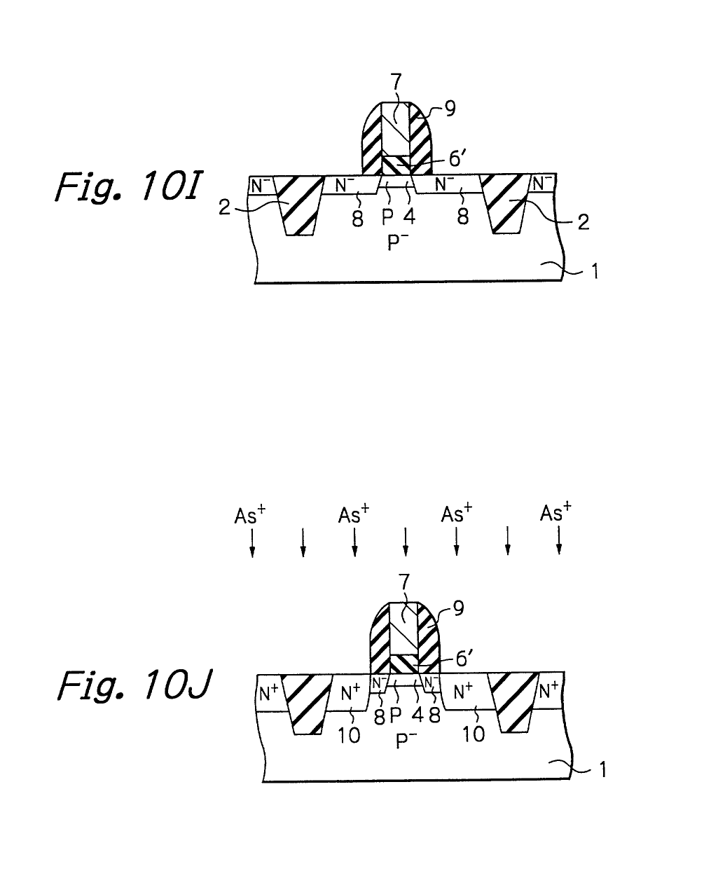

An embodiment of the method for manufacturing a semiconductor device according to the present invention is explained next with reference to FIGS. 10A through 10J.

First, referring to FIG. 10A, in the same way as in FIG. 1A, an STI layer 2 made of silicon oxide for isolating elements from each other is buried in a P⁻-type monocrystalline silicon substrate 1. Then, an about 20 nm thick sacrifice silicon oxide layer 3 is grown by thermally oxidizing the silicon substrate 1. Then, boron ions are implanted into the silicon substrate 1 to form a P-type impurity diffusion region 4 within the silicon substrate 1. Note that the P-type impurity diffusion region 4 is used for adjusting the threshold voltage of an N-channel MOS transistor which will be formed.

Next, referring to FIG. 10B, in the same way as in FIG. 1B, the sacrifice silicon oxide layer 3 is removed by an etching process using a diluted fluoric acid solution for about 1.5 minutes.

Next, referring to FIG. 10C, in the same way as in FIG. 1C, the device is cleaned and rinsed by ammonium hydrogen peroxide and sulfuric acid hydrogen peroxide. As a result, an about 1 nm thick chemical or natural silicon oxide layer 5 is formed on the entire surface.

Next, referring to FIG. 10D, in the same way as in FIG. 1D, the natural silicon oxide layer 5 is removed by an etching process using a diluted fluoric acid solution of 49 percent HF/H₂O=1/100 at a temperature of about 25° C.

Next, referring to FIG. 10E, an about 2.7 nm silicon oxide nitride (SiON) gate insulating layer 6′ is grown in a low pressure CVD (LPCVD) apparatus in a tetrachlorosilicon TCS(SiCl₄)/nitrogen oxide (N₂O) atmosphere at a temperature of about 650° C. at a pressure of about 8 Torr (1067 Pa). Note that a rapid thermal CVD apparatus can be used instead of the LPCVD apparatus. Also, hexachlorodisilicon (Si₂Cl₆) or tetrafluorosilicon (SiF₄) can be used instead of TCS. Further, NO or, NO₂ can be used( as nitrogen oxide, and mixture gas of two or more of N₂O, NO, NO₂, N₂ and O₂ can be used as nitrogen oxide.

Next, referring to FIG. 10F, in the same way as in FIG. 1G, a heating process is carried out in an oxygen atmosphere at a temperature of about 800° C. for about 10 seconds at a atmospheric pressure. Then, an about 150 nm thick polycrystalline silicon layer 7 is deposited on the entire surface by a CVD process at a temperature of about 620° C.

Next, referring to FIG. 10G, in a similar way to those of FIG. 1H, the polycrystalline silicon 7 and the gate insulating layer 6′ are patterned by a photolithography and etching process. As a result, the etched polycrystalline silicon layer 7 forms a gate electrode.

Next, referring to FIG. 10H, in the same way as in FIG. 1I, arsenic ions are implanted into the silicon substrate 1 by using the polycrystalline silicon layer 7 as a mask. As a result, an N⁻-type impurity diffusion region 8 for an LDD structure is formed within the silicon substrate 1.

Next, referring to FIG. 10I, in the same way as in FIG. 1J, a silicon oxide layer is deposited on the entire surface by a CVD process, and the silicon oxide layer is etched back by an anistropic etching process. As a result, a side-wall silicon oxide layer 9 is formed on the side-walls of the polycrystalline silicon layer 7 and the gate insulating layer 6′.

Finally, referring to FIG. 10J, in the same way as in FIG. 1K, arsenic ions are implanted into the silicon substrate 1 by using the polycrystalline silicon layer 7 and the side-wall silicon oxide layer 9 as a mask. As a result, an N⁺-type impurity diffusion region 10 as a source/drain region is formed within the silicon substrate 1.

Thus, an N-channel MOS transistor is completed.

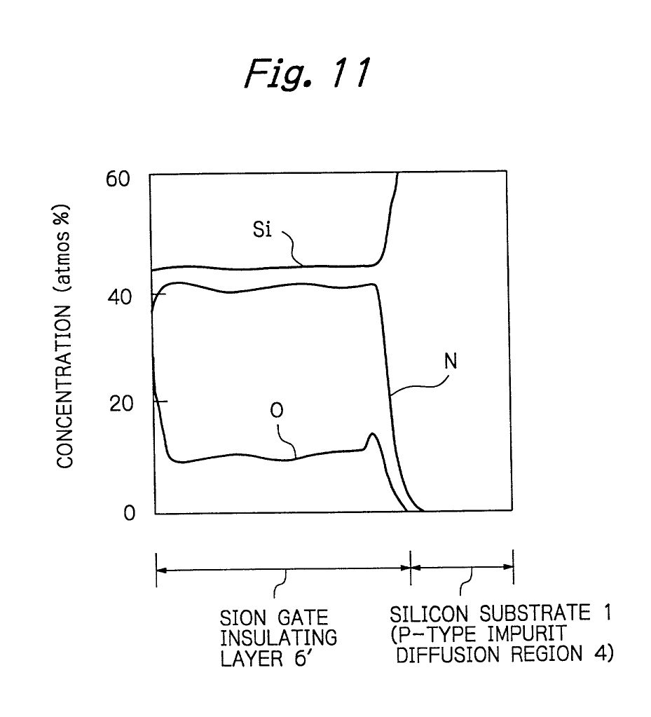

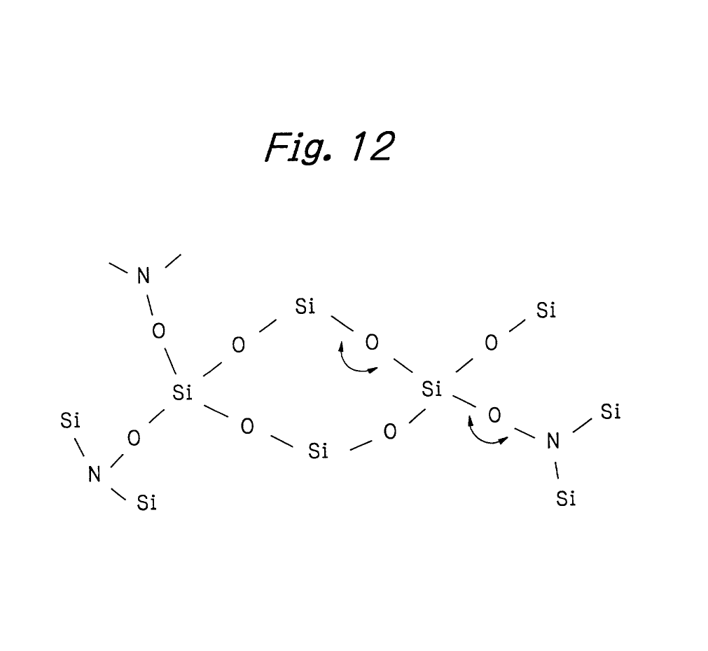

FIG. 11 is a graph showing the nitrogen, oxygen, hydrogen and silicon concentration of the gate insulating layer 6′ of FIG. 10J and FIG. 12 is a diagram showing the structure of the gate insulating layer 6′ of FIG. 10J.

As illustrated in FIG. 11, oxygen and nitrogen are uniformly introduced into the SiON gate insulating layer 6′. For example, if X is the number of oxygen atoms in the SiON gate insulating layer 6′ and Y is the number of nitrogen atoms in the SiON gate insulating layer 6′,

Z=X/Y=0.01˜0.5

Also, the deviation ΔZ/Z₀ within the entire SiON gate insulating layer 6′ satisfies:

−0.5/nm<ΔZ/Z₀<0.5/nm

where Z₀ is the average value of Z within the entire SiON gate insulating layer 6′.

As illustrated in FIGS. 11 and 12, no hydrogen atoms are introduced into the SiON gate insulating layer 6′. As a result, weak bonds of Si—H are not generated in the SiON gate insulating layer 6′.

Also, as illustrated in FIG. 11, there is no mismatch interface within the SiON gate insulating layer 6′, which does not create a large physical stress and a crystal defect such as dangling bonds.

Further, a illustrated in FIG. 12, some of silicon atoms are bonded via oxygen atoms with silicon atoms or nitrogen atoms. Since the coupling angle of Si—O—Si and the coupling angle of Si—O—N are relatively free, the freedom of the bonds is large which would not create stress in the SiON gate insulating layer 6′.

Since there are no weal bonds of Si—H in the SiON gate insulating 6′ the number of electron traps therein is decreased, which would improve the hot carrier immunity characteristics.

Even when the hot electrons are injected into the SiON gate insulating layer 6′, few interface states are formed therein. Therefore, the fluctuations of a threshold voltage and an ON-current are suppressed, and also a leakage current is suppressed.

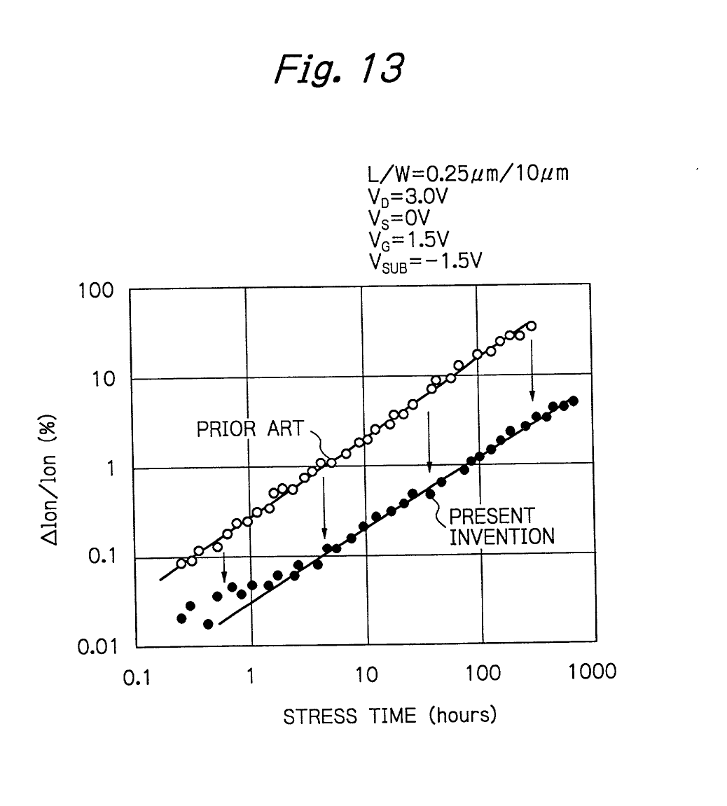

In FIG. 13, which shows the ON-current deviation characteristics of the MOS transistor of FIG. 10J, since the weak bonds of Si—H are removed from the SiON gate insulating layer 6′, the ON-current deviation characteristics are improved by the hot carrier immunity characteristics.

Also, the above-mentioned large freedom of Si—O—Si and Si—O—N bonds suppresses the generation of positive fixed charges in the SiON gate insulating layer 6′. As a result, the presence of no positive fixed charges in the SiON gate insulating layer 6′ can be observed as the improvement of deviation of a flat band voltage V_{FB} as shown in FIG. 14 and an ON-current as shown in FIG. 15.

As shown in FIG. 14, the flat band voltage V_{FB} is shifted back on the positive side, which shows the absence or a small number of positive fixed charges in the SiON gate insulating layer 6′.

As shown in FIG. 15, the ON-current is increased, which also shows the absence or a small number of positive fixed charges in the SiON gate insulating layer 6′.

The reduction of the physical stress and the crystal defect such as dangling bonds are observed by a TDDB test as shown in FIG. 16, where a stress current density −1.0 A/cm² is forced to flow through the gate insulating layer 6′ at a temperature of about 25° C. That is, the voltage applied to the gate electrode 7 hardly fluctuates, which shows a small number of traps in the SiON insulating layer 6′. Additionally, the stress time at the breakdown point is increased, which shows a large lifetime, i.e., a high reliability.

In the above-described embodiment, although an STI layer is provided for isolating the elements from each other, a field insulating layer formed by a local oxidation of silicon (LOCOS) process can be provided instead of the STI layer.

As explained herinabove, according to the present invention, since there are no weak bonds of Si—H in the gate insulating layer so that the number of electron traps therein is decreased, the hot carrier immunity characteristics can be improved. Also, since oxygen is introduced into the gate insulating layer so that few interface states are induced by the small freedom of Si—N—Si bonds, the fluctuations of a threshold voltage and an ON-current can be suppressed. Further, since physical stress and crystal defect such as dangling bonds due to the double structure are suppressed, the lifetime be increased and the reliability can be improved.

What is claimed is:

1. A method for manufacturing a semiconductor device, comprising the steps of:
forming a silicon oxide nitride (SiON) layer on a silicon substrate; and
forming a gate electrode layer on said silicon oxide nitride layer.

2. The method as set forth in claim 1, wherein said silicon oxide nitride layer forming step forms said silicon oxide nitride layer by using silicon generating gas excluding hydrogen and ammonium gas and gas including oxygen atoms and nitrogen atoms.

3. The method as set forth in claim 2, wherein said silicon generating gas excluding hydrogen is one of tetrachlorosilicon (SiCl₄), hexachlorodisilicon (SiCl₄) and tetrafluorosilicon (SiF₄).

4. The method as set forth in claim 2, wherein said gas including oxygen atoms and nitrogen atoms is one of N₂O, NO and NO₂.

5. The method as set forth in claim 2, wherein said gas including oxygen atoms and nitrogen atoms is two or more of N₂O, NO, NO₂ and O₂.
